(19) United States
(12) Patent Application Publication
(10) Pub. No.: US 2014/0034121 A1
(43) Pub. Date: Feb. 6, 2014

(54) MULTISTAGE SURFACE MODIFICATION PROCEDURE OF SEMICONDUCTING NANOPARTICLES FOR USE IN HYBRID SOLAR CELLS AND PRINTABLE ELECTRONICS

(71) Applicant: BAYER INTELLECTUAL PROPERTY GMBH, Monheim (DE)

(72) Inventors: Frank RAUSCHER, Clawson, MI (US); Phenwisa NIYAMAKOM, Koeln (DE); Werner HOHEISEL, Koeln (DE); Sascha PLUG, Leverkusen (DE)

(73) Assignee: BAYER INTELLECTUAL PROPERTY GMBH, Monheim (DE)

(21) Appl. No.: 14/050,189

(22) Filed: Oct. 9, 2013

Related U.S. Application Data
(63) Continuation of application No. 13/821,547.

(30) Foreign Application Priority Data
Sep. 14, 2010 (EP) 10176561.8

(51) Int. Cl. H01L 31/0352

(52) U.S. Cl. CPC H01L 31/035218
USPC 136/255; 257/9; 554/75; 556/118; 252/519.2

(57) ABSTRACT

The present invention relates to a method for treatment of semiconducting nanoparticles wherein in a step A semiconducting nanoparticles comprising long chain insulting primary ligands are dispersed in a volatile dispersion solvent capable of dissolving insulating primary ligands and precipitated using a washing agent. TGA-MS analysis shows that the treatment according to the method of the present invention allows complete removal of the outer layer of synthesis ligands of the surface of prepared nanoparticles and improves removal of synthesis ligands on the surface of prepared nanoparticles. The present invention also relates to semiconducting nanoparticles, ink formulation and electronic devices comprising the semiconducting nanoparticles obtainable by the procedure of the invention.

### CROSS REFERENCE TO RELATED APPLICATIONS

This application is Continuation of U.S. application Ser. No. 13/821,547, filed Mar. 7, 2013, which is a §371 National Stage Application of PCT/EP2011/065839, filed Sep. 13, 2011, which claims priority to European Application No. 10176561.8, filed Sep. 14, 2010, the content of all of which are incorporated herein by reference in their entireties.

### BACKGROUND OF THE INVENTION

1. Field of the Invention

The present invention relates to a method for surface modification procedure of semiconducting nanoparticles, ink formulation and electronic devices comprising the semiconducting nanoparticles obtainable by the procedure of the invention.

2. Description of Related Art

Solar cells or photovoltaic cells (PV cells) are electronic devices, which convert light energy directly into electric energy.

Many different types of solar cells are known in the art. For example silicon-based solar cells are obtained from monocrystal silicon wafer as they are used for the manufacture of semiconductors. This manufacture process is rather expensive.

With the aim of reducing production costs organic solar cells have been developed in the recent years.

An organic cell is made of organic material that is hydrocarbon compounds and particularly polymers. The advantage of a polymer solar cell compared with the silicon solar cells are:
lower production costs,
high current efficiency through thin layer-large scale technology, flexibility, transparence and easy handling (physical properties of polymer materials) environmental friendly (carbon-based material)
easy adjustment to the light spectrum through selective polymer production,
Colored solar cells for architecture design.

However current organic solar cells show reduced energy conversion efficiency and lifetime compared to solar cells based on inorganic semiconducting material.

The most efficient organic solar cells make use of Donor-Acceptor (D-A) systems that is of the combination of semiconducting materials, which after light absorption allow quasi instantaneous (<<1 ps) transfer of a charge carrier between donor and acceptor (i.e. combination of polymer and fullerenes). Absorption of photons with energy higher than the gap between the highest occupied molecular orbital (HOMO) and the lowest unoccupied molecular orbital (LUMO) of either D or A triggers production of excitons which split up for a short time due to local electric field on the D-A contact surface. The transport of the charge carrier occurs selectively in the semiconductor after the split. The charge carrier hops within an amorphous or niicrocrystalline semiconducting comprising a whole range of energy barriers in a disordered way. Thereby carriers also meet molecule and phase limits, and recombine so the charge split is lost.

Hybrid solar cells aim to combine the properties of the inorganic and organic cells (high current efficiency, high life time and lower production costs as well as light and flexible 10 product). U.S. Pat. No. 6,878,871 describes hybrid solar cells comprising semiconducting nanoparticles arranged in a photoactive organic layer.

The active layer system of these hybrid solar cells also named “bulk heterojunction cells” and of other printable electronics devices consists of a nanostructured composite of semiconducting nanoparticles and semiconducting polymers produced by deposition of a dispersion of a mixture of both components on a substrate. Further additives may be optionally added for improving the nanostructure to achieve a better performance.

The semiconducting nanoparticles are usually synthesized by a solvothemtal process that implies a primary ligand layer around the surface to shield the nanoparticles from unintentional agglomeration and to provide a stable dispersion, (for example DE102006017696 or DE102006055218). However, this ligand layer consists of mostly hydrophobic long-chain ligands, e.g. trioctylphosphine (TOP), trioctylphosphine oxide (TOFU), oleic acid (OA), tetradecylphosphonic acid (TDPA), tri-n-Butylphosphine (TBP), octylphosphonic acid (OPA) or other, which, however, act as an electrically insulating layer hindering an efficient charge separation between nanoparticles and polymer and/or transport between nanoparticles. The use of those semiconducting nanoparticles without an appropriate surface modification leads to hybrid solar cells or other printable electronics devices with very low performance.

Therefore, the problem to be solved is the substitution of the primary ligand layer by other intermediate ligands. These ligands should on one hand side ensure a stable/metastable dispersion of semiconductor nanoparticles and polymers and on the other hand enable a charge transfer from or to the nanoparticles and between them. Ideally, the new exchanged ligands have then to be removed in the solar cell active layer or in the printable electronics devices by annealing and/or vacuum steps to further improve the conductivity between the nanoparticles as well as to ensure an efficient charge separation and/or transport between nanoparticles and polymer.

Thermo Gravimetric Analysis-Mass Spectrometry (TGA-MS) measurements conducted as described in example 1 and shown in FIG. 2 provided more detailed information of surface chemistry on semiconductive CdSe nanoparticles obtained after synthesis using known procedure.

The prepared CdSe nanoparticles were shown to be surrounded by primary ligands (from the synthesis) as three different layers (FIG. 1).
Layer A—The excess primary ligands from the synthesis, in the case of CdSe quantum dot are trioctylphosphine (=TOP) and oleic acid (=OA) and in the case of CdSe nanorod are trioctylphosphine (TOP), trioctylphosphine oxide (TOPO) and tetradecylphosphonic acid (TDPA). It makes ca. 15%-20% by weight of primary ligands. Excess primary ligands in this layer bind loosely on the surface as it was found by TGA-MS that this layer will evaporate from the nanoparticle at 100° C.-200° C.
Layer B—The layer represents the outer layer of primary ligands from the synthesis. It makes ca. 3%-5% by weight of synthesis ligands. TGA-MS results show that this layer will evaporate from the nanoparticle at 300° C.
Layer C—The layer is the part where primary ligands bind tightly onto the nanoparticle surface (ca. 20% by weight). Ligands in this layer will always be in the active layer of hybrid solar cell since they will evaporate only from 400° C. or even higher. The primary ligands in this layer can only be removed partially by refluxing in a shorter ligand (for example pyridine).

It is known that following a defined procedure for the post-synthesis treatment of the semiconducting nanoparticles is advantageous for the ink formulation leading to higher performance printable electronics devices. In particular the used procedure should provide a final solution dispersion of produced semiconducting nanoparticles which is homogeneous and stable.

It would be advantageous to provide a procedure optimizing ligand exchange and in particular capable to remove primary ligands of layer B easily and reliably to optimize the surface of the nanoparticles for ligand exchange.

Ligand exchange on the surface of semiconducting nanoparticles is well-known in the state of the art. Pyridine refluxing is a widely used as the post-synthesis processing of the ligand exchange for semiconducting nanoparticles (B. Sun and N. C. Greenham, Phys. Chem. Chem. Phys., 8 (2006) 3557-3560; B. Sun et al., J. Appl. Phys. 97 (2005) 014914; C. B. Murray et al., J. Am. Chem. Soc. 115 (1993) 8706-8715; E. Zenkevich et al., International Journal of Photoenergy (2006) 90242, 1-7; M. Law, J. M. Luther, Q. Song, B. K. Hughes, C. L. Perkins and A. J. Nozik, J. Am. Chem. Soc. 130 (2008) 5974-5985)

The ligand exchange by other ligand, such as n-butylamine, is also claimed to be a promising method to solve the problem of final solution dispersion (US2007/0132052A1). A good solubility of semiconducting nanoparticle-solution without a sign of aggregation can be achieved by n-butylamine treatment, instead of pyridine. The difference between these two ligands is the temperature during the surface modification of semiconducting nanoparticles; n-butylamine can be partially exchanged at lower temperature, and particularly at room temperature.

Further, the use of bifunctional short-chain, ligands was disclosed by J. Haremza et al. [J. Haremza, M. Hahn, T. Krauss, S. Chen, and J. Calcines; Nano Letters 2(2002) 1253-1258] who applied 2-aminoethanethiol to covalently crosslink CdSe nanoparticles with carboxylated single walled carbon nanotubes (SWCNT). B. Landi et al, proposed the use of 4-aminothiophenol to couple CdSe nanoparticles to SWCNT [Brian J. Landi et al.; Materials Letters, 60 (2006) 3502].

Conducted experiments and TGA-MS analysis of produced nanoparticles show that primary ligands of layer B can be completely removed by refluxing in a shorter ligand (for example pyridine), or partially removed by ligand exchange at room temperature (for example n-butylamine).

An alternative post-synthesis procedure comprises the semiconducting nanoparticles being washed with methanol prior to ligand exchange (US2007/0132052A1). The washed semiconducting nanoparticles are then treated to remove the insulating primary ligands being necessary for the synthesis to substitute them with preferably low molecular weight, volatile and/or fairly conductive species without causing agglomerations. TGA-MS analysis conducted on the washed nanoparticles show that methanol washing only achieves partial removal of layer B (FIG. 3, experiment 2).

### SUMMARY

The object of the present invention is to provide a practical method capable of substituting the primary ligand layer by other intermediate ligands easily and reliably. In particular the method should remove primary ligands of layer to optimize the surface of the nanoparticles for ligand exchange. The method should provide on one hand side a stable/metastable dispersion of semiconductor nanoparticles in polymers and on the other hand enable a charge transfer from or to the nanoparticles and between them for effective use in solar cells.

The first object of the present invention is a method for the treatment of the semiconducting nanoparticles wherein in a step A semiconducting nanoparticles comprising long-chain insulating primary ligands are dispersed in a volatile dispersion solvent capable of dissolving insulating primary ligands and precipitated using a washing agent.

### BRIEF DESCRIPTION OF THE DRAWINGS

FIGS. 1-4B represent embodiments as described herein.

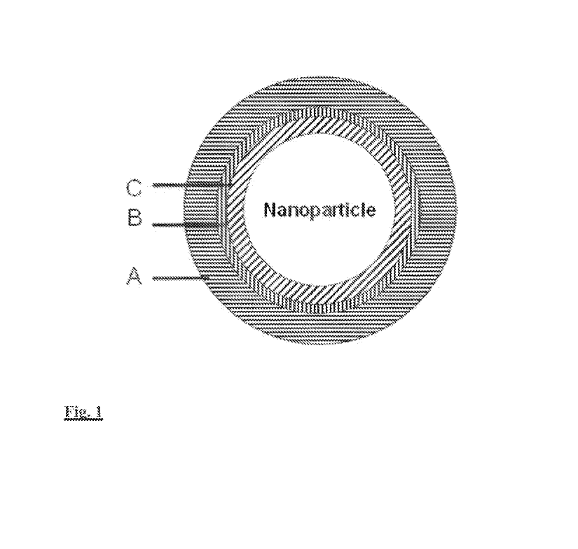

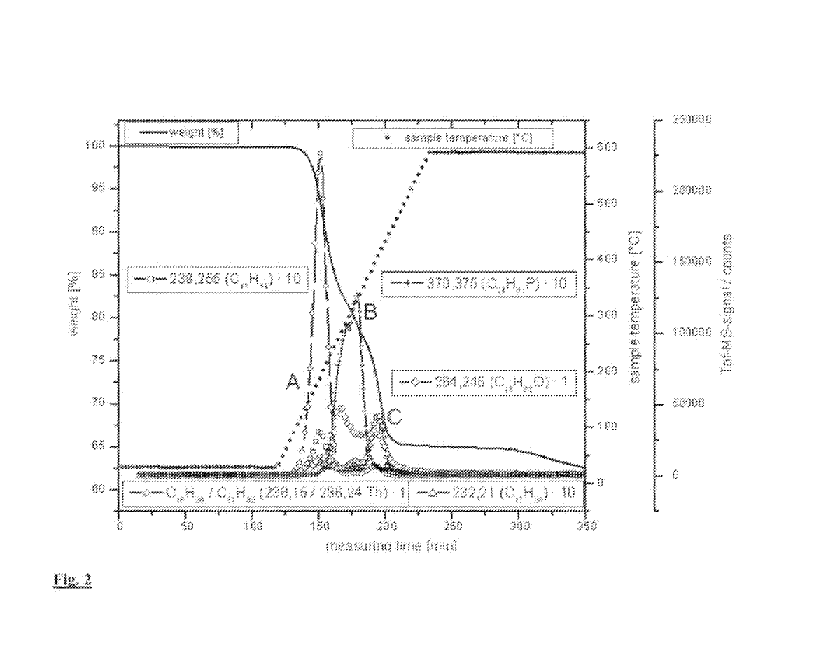

### DETAILED DESCRIPTION OF A PREFERRED EMBODIMENT

Usually in a further step B the semiconducting nanoparticles of step A are treated with solutions of one or more substitution ligands to substitute insulating primary ligands at the surface of semiconducting nanoparticles with the substitution ligands.

Nanoparticles of the present invention are inorganic semiconducting nanoparticles in form of quantum dots (QD), rianorods (NR), tripods, tetrapods or other multipods, which comprise at least one of PbS, InAs, InP, PbSe, CdS, CdSc, CdTe, In,Gai,As, (Cd—Hg)Te, ZnSc(PbS), ZnS(CdSe), ZnSe(CdS), PbO(PbS), CulnS₂, CuInSel and PbSO₄(PbS).

Usually the washing agent also used in step A is poured into the semiconducting nanoparticle dispersion from the synthesis and the precipitate is subsequently centrifuged before step A is conducted.

Washing step (step A) essentially removes hydrophobic long-chain primary ligands in excess (layer A) and to a minor degree also some ligands attached to the nanoparticle surface (layer B).

Step A is usually conducted at a temperature from 15° C. to 40° C., preferably 18° C. to 30° C., most preferably at room temperature

Suitable washing agents are alcohols like methanol, ethanol, propanol, or higher linear (C4 to C8 containing alcohol) or branched alcohols (such as mono-methylated alcohols, polyisoprenoid alcohols, isobutyl alcohol, sec-butyl alcohol, tert-butyl alcohol, as well as mixtures thereof. Methanol, ethanol and propanol as well as mixtures thereof are preferred.

The washing agent (is particular methanol) facilitates the removal of excess original ligands from the surface of semiconducting nanoparticles due to the strong polarity of the washing agent.

Examples of suitable dispersion solvents are n-hexane, petroleum ether or higher species including their isomers and mixtures thereof, preferably n-hexane. Dispersion solvents applied during the washing step help dissolve and remove excess hydrophobic long-chain primary ligands so a redispersable dry powder can be obtained.

100 mg of nanoparticles are usually dispersed in 1 ml of dispersion solvent and washing agent is added to a ratio of dispersion solvent to washing agent of 1.5 to 1:100, preferably 1:5 to 1:50, most preferably 1:5 to 1:20. Semiconducting nanoparticles precipitate and the precipitate is usually separated using centrifugation method.

The washing step A is preferably repeated at least one time, preferable three times.

After washing, the re-precipitation of semiconducting nanoparticles by methanol shows clear supernatant after a short time of centrifugation, which facilitates time consumption as well as the removal of rest primary ligands.

Semiconducting nanoparticles are usually isolated by centrifugation or other method known in the art. Then they are optionally dried under nitrogen flow under an inert atmosphere to prevent oxidation or other undesired reactions for analysis.

A redispersable dry powder is obtained after washing and drying.

TGA-MS analysis shows that the washing according to the method of the present invention allows complete removal of the outer layer of synthesis ligands on the surface of prepared nanoparticles and improves removal of synthesis ligands on the surface of prepared nanoparticles.

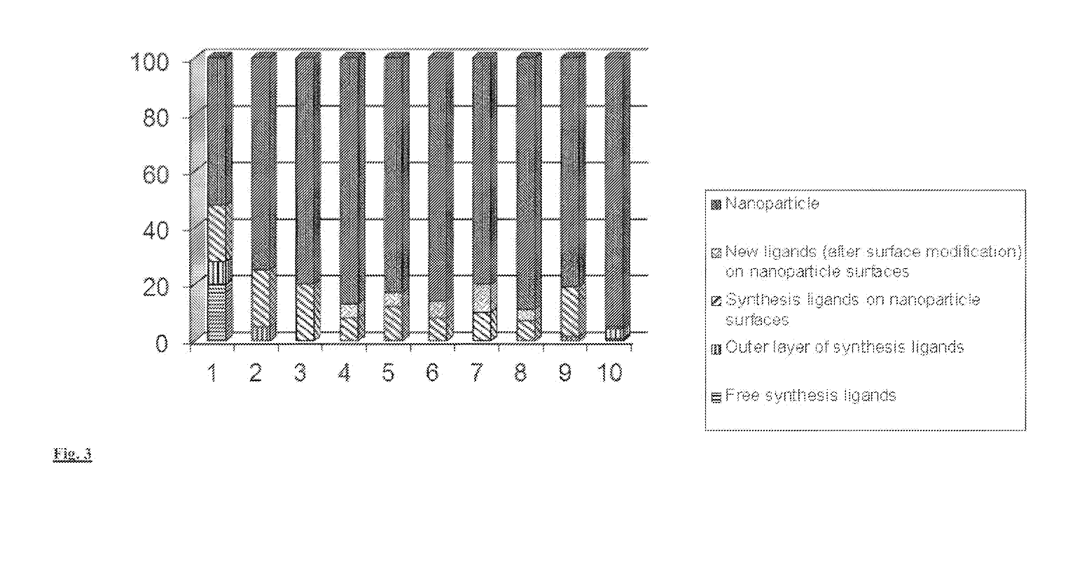

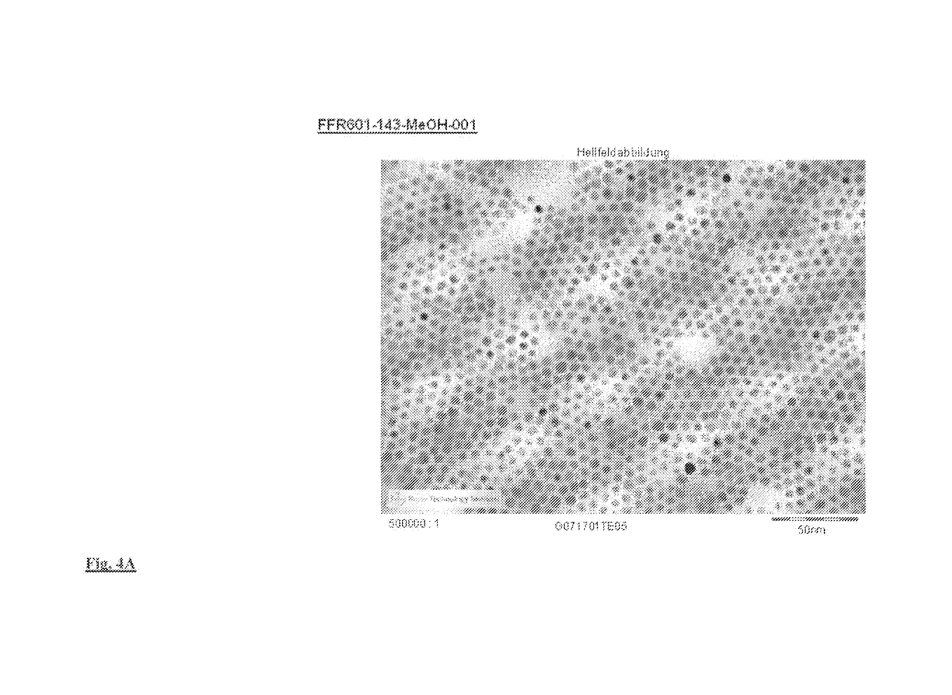

FIGS. 2 and 3 show the weight percentage of the component of the nanoparticles of the present invention at the different stages of their preparation procedure measured by TGA-MS as described in detail in example 1.

Measurement 1 shows the composition of the nanoparticles after synthesis.

Measurement 2 shows the composition of the nanoparticles after methanol washing according to the method of US2007/0132052A1.

Measurement 3 shows the composition of the nanoparticles after the MeOH/n-Hexane washing according to the present invention.

FIGS. 2 and 3 clearly shows that the outer layer of synthesis ligands was most efficiently remove using the washing procedure of the present invention.

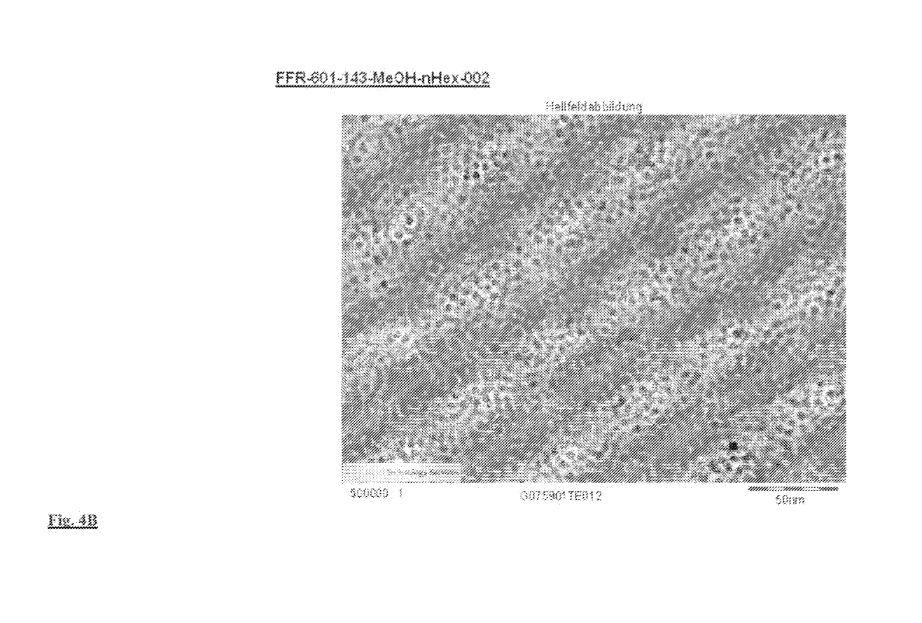

FIG. 4 shows pictures taken by Transmission electron microscopy (FEI Tecnai 20) of nanoparticles after washing according to the process of US2007/0132052A1 using methanol and particles after washing according to the present invention. The process of the present invention shows that interdistance between nanoparticles decreases which an indicator of improved uniformity of nanoparticle surface compared to known MeOH washing procedure.

To remove the long-chain insulating primary ligands from the semiconducting nanoparticle surface and exchange those with intermediate species (step B) the nanoparticles of step A are treated with solutions containing one or more substitution ligands (=intermediate ligand) in a solvent capable of dissolving substitution ligands.

It was found that the selection of the substitution ligands can further improve the efficiency of hybrid solar cell comprising these semiconducting nanoparticles.

For the ligand exchange to occur substitution ligands are usually selected according to their ligand affinity to the used particles which should be in the same range as the affinity of the insulating primary ligands from the synthesis (e.g. trioctylphosphine (TOP), trioctylphosphine oxide (TOPO), oleic acid (OA), tetradecylphosphonic acid (TDFA), tri-n-Butylphosphine (TBP), octylphosphonic acid (OPA) or other high-boiling hydrophobic ligands).

In a dispersion of semiconducting nanoparticles without ligands, the interdistance between nanoparticles is too small and uncontrolled agglomeration of nanoparticles occurs due to attractive van der Waals forces. This agglomeration is unfortunately is irreversible.

To use semiconductor nanoparticle as an ink for the fabrication of solar cells or other electronic devices, it is preferred that the ink is a stable and homogeneous dispersion to obtain good film quality after spin-coating this ink onto a substrate to obtain an active layer. Hence, ligands are necessary in this case.

However after having prepared such an active layer, good nanoparticle-nanoparticle contacts, eventually as well as nanoparticle-polymer contacts within site active layer are needed for optimal charge transport. Ligands can hinder charge transport, so a volatile ligand is preferred, which may be removed by annealing active layer in a further step of the fabrication of the electronic device.

Alternatively it is preferred that ligands are fairly conductive so they can contribute to charge transports within the active layer.

As complete removal can not be achieved by annealing it is preferred that ligands are volatile and fairly conductive to further improve performance of obtained solar cells

As a summary substitution ligands are preferable which:

a. are volatile, i.e. have a low boiling point (≦150° C.) in order to open up the possibility for easy evaporation during the annealing step after formation of the active layer,

b. have a low molecular weight (≦100 g/mol) or a short chain (C2 to C8) linear, Branched, (hetero)cyclic or (hetero)aromatic from monocyclic to polycyclic with 3 cycles,

c. do not form a covalent bond to the semiconducting nanoparticles,

d. provide a stable ink without agglomerates of a size >100 nm (preferred 20 nm, especially preferred no agglomerates) also when mixed with a second semiconducting material.

For further use of produced semiconductor nanoparticles in an ink for the production of electronic devices and in particular in solar cells it is most preferable that these ligands also:

e. assure a better electron or hole conductivity than with the primary insulating long-chain ligands. Substitution ligands comprising at least one π-electron system i.e. double bond and/or aromatic system are preferred.

Suitable substitution ligands for surface modification of semiconducting nanoparticles according to step B can be divided into three different classes, i.e. amines, thiols and electroactive surfactants.

In a preferred embodiment of the invention ligands with functional groups containing nitrogen, sulfur, carbon or phosphor are used for this procedure. Preferred are amines, thiols, thiophenes, carboxyl or phosphates having either short tail or side groups (Mw≦100 g/mol) or being alkenes, cycloalkenes, aromatic ring systems or polycyclic. Examples for nitrogen containing functional groups are Pyrrol, Indol, Isoindol, Imidazol, Benzimidazol, Purin, Pyrazol, Indazol, Oxazol, Benzoxazol, Isoxazol, Benzisoxazol, Pyridin, Isochinolin, Pyrazin, Pyrimidin, Pyridazin or Cinnolin. Further examples are heterocyclic polycyclic aromatic compounds like Chinolin, Isochinolin, Chinoxalin, Acridin, Chinazolin, Carbazole. Examples for sulfur containing functional groups are Thiophen, Benzothiophen, Thiazol, Benzothiazol. Further preferred are n-alkyl-amine (2≦n≦8), di-n-alkylamin (2≦n≦4), vinylamin, allylamin, propenamin, divinylamin, Diallylamin, dipropenamin, pyridine as example.

Bifunctional modifications of the ligands mentioned above are also suitable.

In particular in case of hybrid systems that case of a system consisting of semiconducting nanoparticles and semiconducting polymers, another class of suitable ligands are monomers or oligomers related to the respective semiconducting polymers. These monomers or oligomers are optionally functionalized with amines, thiols or phosphates.

Also suitable are thermal or UV-cleavable ligands such as tert-butyl-N-2-(mercaptoethylcarbamate) (=tBOC) or other carbamate-containing molecules.

Two or more types of the above mentioned ligands can be used for the ligand exchange Process. In this case the different types of ligands can be applied in one step as mixtures of the according solutions or in sequential steps.

Solvents capable of dissolving substitution ligands used in step B are preferably volatile with a boiling point below 150° C. (high vapour pressure). Preferred solvents are e.g. toluene, xylene, methylen chloride, chloroform, chlorobenzene, di-chlorobenzen, tri-chlorobenzene.

Substitution ligands containing amines as functional group are particularly preferred because it is well known that they significantly influence the semiconductor nanoparticle surface by passivating defect sites or enable a chemical etching process e.g. by redox cycles to remove surface defect sites. This is advantageous since a lower defect density on the particle surface also means a lower density of recombination centers, a prerequisite for a higher printed electronic device performance.

The process of the ligand exchange may involve external energy supply like heating or light illumination. Ligand exchange may occur both at high (in case of pyridine refluxing) and at low temperature (in case of n-butylamine, for example). It may be advantageous to repeat the process of the ligand exchange several times under the same or under different conditions.

The treated semiconducting nanoparticles of step B are usually washed.

Treatment of step B is achieved without causing agglomerations of semiconducting nanoparticles after washing for removal of excess intermediate ligands.

After surface modification of step B, the precipitation of semiconducting nanoparticles by methanol shows clear supernatant after a short time of centrifugation, which facilitates the time consumption as well as the removal of excess intermediate ligands.

The surface analytics of treated semiconducting nanoparticles provide information of ligand exchange on the surface of semiconducting nanoparticles.

Both washing (step A) and selection of the substitution ligands were shown to lead to an optimization of the surface of the semiconducting nanoparticles produced by the procedure of the present invention, particularly useful for hybrid solar cell fabrication.

Further object of the invention is therefore semiconducting nanoparticles obtainable according to the method of the present invention.

The semiconducting nanoparticles according to the present invention and optionally the second semiconducting material (hybrid system) may be dispersed in an ink solvent (step 3) to form a stable/metastable, homogeneous ink. Additives may be applied to improve or modify properties of obtained ink.

In case a second soluble semiconductor material is involved in further use of semiconducting nanoparticles of step B (for example in the active layer of a hybrid system) these latter are transferred into a common ink solvent also compatible with the second semiconducting material.

The semiconducting nanoparticles and optionally the second semiconducting material should form a stable/metastable, homogeneous dispersion in the ink solvent.

The ink solvent is preferably volatile with a boiling point below 130° C. (high vapour pressure). Preferred solvents are e.g. toluene, xylene, methylen chloride, chloroform, chlorobenzene, di-chlorobenzene, tri-chlorobenzene.

Additionally, further additives may be applied to increase performance of the printable electronic devices.

A hybrid system in the sense of the present invention comprises semiconducting nanoparticles and semiconducting polymers as second semiconducting material and in particular a hybrid solar cell.

The second semiconducting material an hybrid system is in the context of the present invention a semiconducting polymer, in perferably capable of crystallization for example conductive polymers such as poly(acetylene)s, polyanilines, poly(pyrrol)s, polyindole, polypyrene, polycarbozole, polyazulene, polyazepin, polyfluorones, polynapthalenes, preferably poly(p-phenylene vinylene), most perferably conductive polymers with a high affinity to nanoparticles such as polythiophenes, poly(3-alkylthiophenes), poly(p-phenylene sulfide). By mean of high affinity, conductive polymers should contain some components, preferable to coordinate physically of chemically with semiconducting nanoparticle surface, such as containing sulfur for using with Cd-based semiconducting nanoparticles.

In case of hybrid systems it is advantageous for the ink formulation leading to high performance printable electronics devices if the crystallization process of the semiconducting polymer is influenced to enhance the charge carrier mobility. Additives may be added to the ink mixture to influence the secondary structure of the semiconducting nanoparticles in the active layer film to improve the pathways for the charge carriers within the semiconducting nanoparticles to their respective electrode. Lower inner resistances and higher efficiencies or better performance of the printable electronics devices can be achieved.

Such additives are well known in the state of the art. Suitable additives are nitrobenzene, octanethiols or dihaloalcanes.

Some additives may also be used in the ink to trigger further detachment of residual long-chain primary ligands from the nanoparticle surface.

Also combinations of these additives may be suitable.

To prepare ink formulation comprising semiconductor nanoparticles and semiconducting polymers, two stocks solutions are usually prepared, one as the nanoparticle stock solution and another as the polymer stock solution. Subsequently, the ink formulation is obtained in mixing the two stock solutions with a suitable weight ratio, depending on semiconductor nanoparticles and semiconducting polymer usually 75:25 to 95:5, preferably 80:20 to 90:10. For example best efficiency a ratio 87:13 NR:Polymer (examples 2, 3, 5, or 6).

Also object of the present invention is an ink comprising the semiconducting nanoparticles of the present invention in an ink solvent.

In a particular embodiment the ink of the present invention also comprises a second semiconducting material able to form a bulk heterojunction with the semiconducting nanoparticles and the ink solvent is compatible for the semiconducting nanoparticles and for the second semiconducting material so that a stable or metastable ink is achieved.

They further ensure high performance of those printable electronic devices such as e.g. hybrid solar cells, which contain semiconducting nanoparticles in essential parts.

Also object of the present invention is an electronic device comprising the semiconducting nanoparticles of the present invention and in particular a solar cell.

In a further step of the method of the invention the ink of step 3 is printed on the surface of a printable electronic device using printing methods well known in the state of the art such as ink-jet printing, screen printing, roll-to-roll printing and dried.

Ideally, the intermediate ligands have then to be removed in the solar cell active layer or in the printable electronics devices by annealing and/or vacuum steps to further improve the conductivity between the nanoparticles as well as to ensure an efficient charge separation and/or transport between nanoparticles and polymer.

Examples of the method and nanoparticles according to the present invention are given without limiting the scope of the present invention to used materials and specific conditions.

### EXAMPLES

### Example 1

### Thermo Gravimetric Analysis-Mass Spectrometry (TGA-MS) Measurement of CdSe Nanoparticle of Quantum Dot Shape (CdSe-QD) with Primary Ligand Trioctylphosphine (=TOP) and Oleic Acid (=OA)

Semiconducting nanopartieles CdSe-QD with primary ligand trioctylphosphine (=TOP) and oleic acid (=OA) were prepared according to the method of US2007/0132052A1

The TGA-MS measurements are performed with dried semiconducting nanoparticles under an inert atmosphere to prevent oxidation or other undesired reactions during the analysis. The amount of the dried sample should he at least 50 mg.

50 mg of dried sample were loaded onto a high-precision balance pan placed in a small electrically heated oven with thermocouple accurately measuring the internal oven temperature.

An inert gas preferably Ar or He and most preferably He with a flow rate of 80 ml/minute was flown into the overt for preferably at least two tours to purge away traces of oxygen and water out of the oven.

Then the temperature of the oven and of the balance pan was gradually increased usually with a gradual temperature increase of 5 K/minute under the inert atmosphere and mass spectroscopy measurements were conducted using a time-of-flight mass spectrometer of type RFT10 provided by company Kaesdorf.

The range of measurement temperature covered the whole range of decomposition of all substances contained in the sample that is from 300 K to 900 K.

As the sample vaporized, the mass spectrometer detected the elemental components of the organic ligand shell of the dried semiconducting nanoparticles as well as molecular fragments thereof and measured their concentrations.

The composition of the organic ligand shell was subsequently calculated qualitatively and quantitatively.

Results of conducted analyses are shown in FIG. 2.

Weight percentage distribution is shown in FIG. 3, column 1.

### Example 2

### Preparation of CdSe-QD with Primary Ligand TOP and OA Using MeOH According to the Method of US2007/0132052A1 and Solar Cell Preparation

A—Washing of CdSe-QD with primary ligand TOP and OA using MeOH according to the method of US2007/0132052A1.

Above mentioned CdSe-QD with primary ligand TOP and OA were prepared and washed with MeOH according to the method of US2007/0132052A1.

Weight percentage distribution obtained alter TGA-MS Analysis according to the method of example 1 is shown is FIG. 3, column 2.

FIG. 4A shows a TEM Picture (made with TEM-FEI Tecnai 20 of CdSe nanoparticles after 3×MeOH washing.

B—Preparation of a solar cell using an ink comprising semiconductor nanoparticles of example 2-A

100 mg of the CdSe-QD with ligand TOP and OA of example 2-A were dispersed in 1 mL of the ink solvent (chlorobenzene) as the first stock solution. The 11 mg of a second semiconducting material (poly(3-hexylthiophene) or P3HT) were dispersed in 1 mL of the ink solvent (chlorobenzene) as the second stock solution. The two stock solutions were mixed with a weight ratio as 90:10 (CdSe-QD:P3HT) to form a stable, homogeneous ink. The ink was spin-coated and dried on a substrate made of indium-tin-oxide coated glass with a layer of Poly(3,4-ethylenedioxythiophene) poly(styrenesulfonate) or PEDOT:PSS to obtain an active layer. Obtained active layer was annealed by heating at a temperature of 120° C. for 5 minutes.

The back electrode was evaporated in a vacuum thermal deposition chamber. 4 nm of calcium and 150 nm of silver layers were deposited on top of the active layer. After the electrode evaporation, the solar cells were annealed by heating at a temperature of 120° C. for 5 minutes.

A maximal power conversion efficiency (ηₘₐₓ, “eta” max), that is the percentage of power converted (front absorbed light to electrical energy) and collected, when a solar cell is connected to an electrical circuit, was measured for obtained solar cell using a solar simulator under the standardized condition of AM1.5 was measured using a 150 W Oriel Solar simulator from Newport. AM refers to air mass and a number refers to air mass coefficient, wherein air mass coefficient characterizes the solar spectrum after the solar radiation has traveled through the earth atmosphere. The AM1.5 is universal used for characterization of solar cell power conversion efficiency.

A maximal power conversion efficiency ηₘₐₓ of 0.15% was measured for the solar cells of example 2.

### Example 3

### Washing of CdSe-QD with Primary Ligand TOP and OA Using MeOH and n-Hexane According to the Method of the Present Invention and Solar Cell Preparation

100 mg of the above mentioned CdSe-QD with primary ligand TOP and OA were precipitated by methanol according to the method of US2007/0132052A1. The semiconducting nanoparticles CdSe-QD were separated from the supernatant by centrifugation and dried with nitrogen gas. The dried semiconducting nanoparticles CdSe were redispersed in 1 ml n-Hexane with a concentration of 100 mg of CdSe nanoparticle per 1 mL of n-Hexane and stirred at room temperature for 12-24 hours. Subsequently 10 ml methanol were added into this dispersion to precipitate semiconducting nanoparticles and to remove further TOP and OA (ratio of dispersion solvent to washing agent 1:10). The precipitate was separated from supernatant by centrifugation. The semiconducting nanoparticles were dried with nitrogen gas and redispersed in 1 ml n-Hexane. Washing was repeated twice as mentioned above and produced CdSe-QD were dried under nitrogen flow.

Weight percentage distribution obtained after TGA-MS Analysis according to the method of example 1 is shown in FIG. 3 column 3.

FIG. 4B shows a TEM Picture (made with TEM-FEI Tecnai 20) of CdSe nanoparticles after 3×MeOH/n-hexane-washing.

100 mg of the CdSe-QD with ligand TOP and OA were dispersed in 1 mL of the ink solvent (chlorobenzene) as the first stock solution. The 11 mg of a second semiconducting material (poly(3-hexylthiophene) or P3BT) were dispersed in 1 mL of the ink solvent (chlorobenzene) as the second stock solution. The two stock solutions were mixed with a weight ratio as 90:10 (CdSe-QD:P3HT) to form a stable, homogeneous ink. The ink was spin-coated and dried on a substrate made of indium-tin-oxide coated glass with a layer of Poly(3,4-ethylenedioxythiophene) poly(styrenesulfonate) or PEDOT:PSS to obtain an active layer. Obtained active layer was annealed by heating at a temperature of 120° C. for 5 minutes.

The back electrode was evaporated in a vacuum thermal deposition chamber. 4 nm of calcium and 150 nm of silver layers were deposited on top of the active layer. After the electrode evaporation, the solar cells were annealed by heating at a temperature of 120° C. for 5 minutes.

An maximal power conversion efficiency ηₘₐₓ of 0.25% was measured for the solar cells of example 3 using the method described in example 2-B.

### Example 4

### Preparation and Washing of CdSe Nanoparticle of Nano Rod Shape (CdSe—NR), Ligand Exchange with a Substitution Ligand Primary Amine, n-butylamine, and Solar Cell Preparation

Semiconducting nanoparticles CdSe—NR with primary ligand trioctylphosphine (TOP), trioetylphosphine oxide (TOPO) and tetradecylphosphonic acid (TDPA)) were prepared according to the method of US2007/0132052A1 and washed according to the procedure described lit example 2.

After last decanting of the supernatant and drying of CdSe—NR by nitrogen gas, the washed CdSe—NR were redispersed in a solution containing 15 ml of n-butylamine as substitution ligand. Exchange was allowed to occur over 5 hours at 75° C. in a warmed oil bath.

The treated CdSe—NR were washed with methanol and dried under nitrogen flow. Ligand exchange was achieved without causing agglomerations of CdSe—NR after washing for removal of excess substitution ligands.

Weight percentage distribution obtained after TGA-MS Analysis according to the method of example 1 is shown in FIG. 3, column 4.

After decanting of the supernatant and drying of n-butylamine capped CdSe—NR by nitrogen gas, 30 mg of the n-butylamine capped CdSe—NR were dispersed in 1 mL of the ink solvent (chlorobenzene) as the first stock solution. The 20 mg of a second semiconducting material (poly[2,6-(4,4-bis-(2-ethylhexyl)-4H-cyclopental[2,1-b;3,4-b′]dithiophene)-alt-4,7-(2,1,3-benzothiadiazole) or PCPDTBT) were dispersed in 1 mL of the ink solvent (chlorobenzene) as the second stock solution. The two stock solutions were mixed with a weight ratio as 87:13 (CdSe—NR:PCPDTBT) to form a stable, homogeneous ink. The ink was spin-coated and dried on a substrate made of indium-tin-oxide coated glass with a layer of Poly(3,4-ethylenedioxythiophene) poly(styrenesulfonate) or PEDOT:PSS under a watch-glass for 5 minutes to obtain an active layer.

The back electrode was evaporated in a vacuum thermal deposition chamber. 4 nm of calcium and 150 nm of silver layers were deposited on top of the active layer.

A maximal power conversion efficiency ηₘₐₓ of 1.64 % was measured using the method described in example 2-B.

### Example 5

### Preparation and Washing of CdSe Nanoparticle of Quantum Dot Shape (CdSe-QD), Ligand Exchange with a Substitution Secondary Amine Ligand Diallylamine

Semiconducting nanoparticles CdSe-QD were prepared and washed as mentioned in example 2

After last decanting of the supernatant and drying of the CdSe-QD by nitrogen gas, 100 mg of washed CdSe-QD were redispersed in a solution containing 1 ml of secondary amine diallylamine as substitution ligand. Exchange was allowed to occur over 12 hours at 20° C.

The treated CdSe-QD were washed with methanol and dried under nitrogen flow. Ligand exchange was achieved without causing agglomerations of CdSe-QD after washing for removal of excess substitution ligands.

Weight percentage distribution obtained a after TGA-MS Analysis according to the method of example 1 is shown in FIG. 3, column 5.

### Example 6

### Preparation and MeOH Washing of CdSe Nanoparticle of Nano Rod Shape (CdSe—NR), Ligand Exchange with a Substitution Tertiary Amine Ligand Pyridine and Solar Cell Preparation

A—CdSe—NR washed with MeOH according to the method of US2007/0132052A1, pyridine exchange and solar cell preparation.

Semiconducting nanoparticles CdSe—NR were prepared and washed with MeOH according to the method of US2007/0132052A1.

After last decanting of the supernatant and drying of CdSe—NR by nitrogen gas, the washed CdSe—NR were redispersed in a solution containing 100 ml of tertiary amine pyridine as substitution ligand. Exchange was allowed to occur over 8 hours under refluxing in the nitrogen atmosphere (Greenham et al., Phys. Chem. Chem. Phys. 8(2006)3557-3560).

The treated semiconducting nanoparticles were washed with n-hexane and dried under nitrogen flow. Ligand exchange was achieved without causing agglomerations of CdSe—NR after washing for removal of excess substitution ligands.

Weight percentage distribution obtained after TGA-MS Analysis according to the method of example 1 is shown in FIG. 3, column 6.

After decanting of the supernatant and drying of pyridine capped CdSe—NR by nitrogen gas, 30 mg of the pyridine capped CdSe—NR were dispersed in 1 mL of the ink solvent (chloroform) as the first stock solution. The 20 mg of a second semiconducting material (poly[2,6-(4,4-bis-(2-ethlhexyl)-4H-cyclopenta[2,1-b;3,4-b′]dithiophene)-alt-4,7-(2,1,3-benzothiadiazole) or PCPDTBT) were dispersed in 1 mL of the ink solvent (tri-chlorobenzene) as the second stock solution. The two stock solutions were mixed with a weight ratio as 87:13 (CdSe—NR:PCPDTBT) to form a stable, homogeneous ink. The ink was spin-coated and dried on a substrate made of indium-tin-oxide coated glass with a layer of Poly(3,4-ethylenedioxythiophene) poly(styrenesulfonate) or PEDOT:PSS under a watch-glass for 5 minutes to obtain an active layer. Obtained active layer was annealed by heating at a temperature of 100° C. for 5 minutes (Dayal et al. Nano Lett. 2010, 10 (1), 239-242).

The back electrode was evaporated in a vacuum thermal deposition chamber. 4 nm of calcium and 150 nm of silver layers were deposited on top of the active layer. After the electrode evaporation, the solar cells were annealed by heating at a temperature of 120° C. for 5 minutes.

A maximal power conversion efficiency ηₘₐₓ of 2.70% was measured using the method described in example 2-B.

B—CdSe—NR without MeOH washing, pyridine exchange and solar cell preparation.

To compare a potential of the MeOH washed CdSe—NR, a solar cell fabrication with pyridined capped CdSe—NR without MeOH washing was performed. The CdSe—NR, direct from the synthesis, were reflux in 100 ml of tertiary amine pyridine as substitution ligand. Exchange was allowed to occur over 8 hours under reflux (Greenham et al., Phys. Chem. Chem. Phys. 8(2006)3557-3560). The solar cell fabrication procedure was the same as mentioned previously in this example.

Weight percentage distribution obtained after TGA-MS Analysis according to the method of example 1 is shown in FIG. 3, column 7.

Solar cell preparation was achieved according to the method described in example 6-A

A maximal power conversion efficiency ηₘₐₓ of 1.70% was measured using the method described in example 2-B. This shows us the improvement of the maximal power conversion efficiency by applying MeOH washing procedure prior to the ligand exchange.

C—CdSe—NR washed with MeOH/n-hexane according to the method of the present invention, pyridine exchange and solar cell preparation.

Semiconducting nanoparticles CdSe—NR with primary ligand trioctylphosphine (TOP), trioctylphosphine oxide (TOPO) and tetradecylphosphonic acid (TDPA)) were prepared according to the method of US2007/0132052A1 and washed according to the procedure described in example 3.

The MeOH/n-hexane washed CdSe—NR were subsequently reflux in 100 ml of tertiary amine pyridine as substitution ligand. Exchange was allowed to occur over 8 hours under reflux (Greenham et al., Phys. Chem. Chem. Phys. 8(2006)3557-3560). The solar cell fabrication procedure was the same as mentioned previously in this example.

Weight percentage distribution obtained after TGA-MS Analysis according to the method of example 1 is shown in FIG. 3, column 8.

Solar cell preparation was achieved according to the method described in example 6-A

A maximal power conversion efficiency ηₘₐₓ of 3.40% was measured using the method described in example 2-B. This shows us the improvement of the maximal power conversion efficiency by applying MeOH washing procedure prior to the ligand exchange.

### Example 7

### Preparation and Washing of CdSe Nanoparticle of Quantum Dot Shape (CdSe-QD), Ligand Exchange with a Substitution Thiol-Containing Ligand, Thiophene

Semiconducting nanoparticles CdSe-QD were prepared and washed as mentioned in example 2.

After last decanting of the supernatant and drying of CdSe-QD by nitrogen gas, 100 mg of washed CdSe-QD were redispersed in a solution containing 1 ml of thiophene as substitution ligand. Exchange was allowed to occur over 12 hours at 20° C.

The treated semiconducting nanoparticles were washed with methanol and dried under nitrogen flow. Ligand exchange was achieved without causing agglomerations of semiconducting nanoparticles after washing for removal of excess substitution ligands.

Weight percentage distribution obtained a after TGA-MS Analysis according to the method of example 1 is shown in FIG. 3, column 9.

### Example 8

### Preparation and Washing of CuInS₂ (CIS) Nanoparticle of Quantum Dot Shape (CIS-QD), Ligand Exchange with a Substitution Ligand Primary Amine, n-butylamine

Semiconducting nanoparticles CIS-QD with primary ligand oleylamine (OLA) were prepared according to the method of J. Am. Chem. Soc. 2008, 130, 16770-16777 and washed according to the procedure described in example 2.

After last decanting of the supernatant and drying of CIS-QD by nitrogen gas, the washed CIS-QD were redispersed in a solution containing 15 ml of n-butylamine as substitution ligand. Exchange was allowed to occur over 5 hours at 75° C. in a warmed oil bath.

The treated CIS-QD were washed with methanol and dried under nitrogen flow. Ligand exchange was achieved without causing agglomerations of CIS-QD after washing for removal of excess substitution ligands.

Weight percentage distribution obtained after TGA-MS Analysis according to the method of example 1 is shown in FIG. 3, column 10.

TABLE 1
Summary of results

| | | TGA-MS of | Eta max of solar |
|---|---|---|---|
| Example | Process | nanoparticles | cells made thereof |
| 2 | 3xMeOH | FIG. 3 column 2 | 0.15% |
| 3 | 3xMeOH/n-hexane | FIG. 3 column 3 | 0.25% |
| 4 | 3xMeOH + nBA | FIG. 3 column 4 | 1.64% |
| | exchange | | |
| 5 | 3xMeOH/+secondary | FIG. 3 column 5 | — |
| | amine exchange | | |
| 6A | 3xMeOH + Pyridine | FIG. 3 column 6 | 2.70% |
| | refluxing | | |
| 6B | Pyridine refluxing | FIG. 3 column 7 | 1.70% |
| 6C | 3xMeOH/n-hexane + | FIG. 3 column 8 | 3.40% |
| | Pyridine refluxing | | |
| 7 | 3xMeOH + thiophene | FIG. 3 column 9 | — |
| 8 | 3xMeOH + nBA | FIG. 3 column 10 | — |
| | exchange | | |

1. A method for the treatment of semiconducting nanoparticles comprising:
A said semiconducting nanoparticles comprising long-chain insulating primary ligands in a volatile dispersion solvent capable of dissolving insulating primary ligands and precipitating using a washing agent.

2. A method according to claim 1, further comprising step B treating said semiconducting nanoparticles of A with a solution of at least one substitution ligand to substitute insulating primary ligands at a surface of semiconducting nanoparticles with the substitution ligand.

3. A method according to claim 1, wherein said washing agent comprises at least one alcohol selected from the group consisting of methanol, ethanol, propanol, and C4 to C8 containing linear or branched alcohols and the volatile dispersion solvent comprises at least one apolar aprotic solvent selected from the group consisting of n-hexane, and petroleum ether or higher species including isomers thereof.

4. A method according to claim 1, wherein A is repeated at least one time, optionally three times.

5. A method according to claim 2, wherein said substitution ligands are selected according to their ligand affinity to the nanoparticles which is in the same range as the affinity of the insulating primary ligands and do not form a covalent bond to the semiconducting nanoparticles.

6. The method according to claim 2, wherein said substitution ligand has a boiling point <150° C.

7. The method according to claim 5, wherein the substitution ligand has a molecular weight <100 g/mol and/or a linear or branched chain from C2 to C8, and/or heterocyclic or heteroaromatic from monocyclic to polycyclic with 3 cycles.

8. The method according to claim 5, wherein said substitution ligand comprises at least one π-electron system.

9. A semiconducting nanoparticle obtainable according to the method of claim 1.

10. An ink comprising semiconducting nanoparticle obtainable according to the method of claim 1 in an ink solvent.

11. An ink according to claim 10, comprising a semiconducting material capable of forming a bulk heterojunction with said semiconducting nanoparticle and said ink solvent, is compatible with the semiconducting nanoparticle and with the second semiconducting material so that a stable or metastable ink is achieved.

12. An electronic device comprising said semiconducting nanoparticle of claim 9.

13. An electronic device obtained by printing said ink of claim 10 on a printable surface.

14. An electronic device according to claim 12, which is a solar ceil.

15. A method according to claim 2, wherein washing agents comprises at least one alcohol selected from the group consisting of methanol, ethanol, propanol, and C4 to C8 containing linear or branched alcohols, and the volatile dispersion solvent comprises at least one apolar aprotic solvents selected from the group comprising n-hexane, petroleum ether or higher species including their isomers and mixtures thereof.

16. The method according to claim 6, wherein the substitution ligand has a molecular weight <100 g/mol and/or a linear or branched chain from C2 to C8, and/or heterocyclic or heteroaromatic from monocyclic to polycyclic with 3 cycles.

17. An electronic device according to claim 13, which is a solar ceil.
